(19) United States
(12) Patent Application Publication
(10) Pub. No.: US 2003/0017696 A1
(43) Pub. Date: Jan. 23, 2003

(54) Method for improving capability of metal filling in deep trench

(75) Inventor: Yu-Sheng Yen, Miaoli (TW)

Correspondence Address: LOWE HAUPTMAN GILMAN & BERNER, LLP, 1700 Diagonal Road, Suite 310, Alexandria, VA, 22314, US

(73) Assignee: United Microelectronics Corp.

(21) Appl. No.: 09/903,669

(22) Filed: Jul. 13, 2001

(51) Int. Cl. H01L 21/44

(52) U.S. Cl. 438/672

(57) ABSTRACT

A method for improving the capability of metal filling in deep trench is disclosed. The method includes a steps of a sputtering process is performed on the copper seed layer and barrier layer on the sidewall of the deep trench, wherein the deep trench is above the substrate and within the dielectric layer. Then, the wafer is placed in the pre sputter chamber, and etching process is performed on the wafer. When the power is low, the chamber us carrying sputter etching process out and the process has the efficient bombardment on the wafer and no plasma damage issue is concerned. Such that the barrier layer and metal layer are getting more conformal on the sidewall of the deep trench, and than the void will not be exist in subsequently metal filling process.

### BACKGROUND OF THE INVENTION

1. Field of the Invention

The present invention generally relates to a method for forming a deep trench in interconnect structure, and more particularly to a method for improving the metal filling in deep trench.

2. Description of the Prior Art

There is a number of issues associated with the utilization of copper interconnects in high-density integrated circuits. For example, copper has a high diffusivity in oxide and silicon, even at room temperature. If copper diffuses from the interconnect wiring into the underlying active electrical devices, then these devices can fail to operate. Therefore, suitable confinement of the copper in the interconnect wires and thus, protection of the electrical devices are imperative.

The standard industry approach for the utilization of copper interconnects is to use barrier metals such as TiN (titanium nitride), Ta (tantalum), TaN (tantalum nitride) and/or WN (tungsten nitride) to prevent copper diffusion from the wires. However, this is a challenging task because barrier layer deposition processes must provide conformal coverage of the dual damascene structure commonly used in present device structure. Moreover, the diffusion properties of the barrier layer in high aspect ratio dual damascene structure must meet high performance criteria.

Copper interconnect can be utilized to carry electricity in microcircuits. Copper is, however, subject to electromigration. Electromigratiom can degrade the performance of copper interconnects, for example by aiding the growth of voids in the interconnects. As a result, copper interconnects may be more subject to failure. The resistance of copper to electromigration is strongly dependent upon the crystal structure of the copper interconnect.

Referring to FIG. 1, is illustrating the formation of deep trench 140 on a substrate 100. A dielectric layer 120 is formed on a substrate 100. Then, a patterned photoresist layer is deposited, exposed, and developed on the dielectric layer 120 by the use of know photolithography techniques. Then, an etching process is performed on the dielectric layer 120 to form a deep trench 140, wherein the deep trench 140 is within the dielectric layer 120 and above the substrate 100.

Then, referring to FIG. 2 and FIG. 3, a barrier layer 160 such as TaN (tantalum nitride) is deposited by PVD method (physical vapor deposition), such as sputtering deposition method on the sidewall of the deep trench 140 and a conductive seed layer 180 such as Cu (Copper) is also deposited by PVD method (physical vapor deposition method) on the barrier layer 160.

Since the TaN (barrier layer) 160 and Cu (conductive seed layer) 180 is not mature to provide a conformal barrier layer/seed layer. This will causes the poor metal 240 fill to form voids 220 in high aspect-ratio deep trench 140, which is not desirable in sub-0.13 μm BEOL (back-end-of-line) damascene process development (shown in FIG. 3). The void 220 in metal trench 140 also causes electromigration fail in reliability test.

### SUMMARY OF THE INVENTION

It is an object of this invention to provide a sputtering etching process in a sputtering chamber for forming a conformal layer on the sidewall of the deep trench.

It is another object of this invention to improve the void existed in subsequent metal filling in deep trench.

In one embodiment, a barrier layer and copper seed layer are deposited subsequently on the sidewall of the deep trench. To avoid the void existed in subsequently metal filling process, in the pre-sputtering chamber, two alternative processes: sputtering deposition process and sputtering etching process. When the power is lower than 200 watt, the chamber is carrying sputtering etching process out. And at this power, the charging issue on wafer surface can be avoided. Beside, when the power is higher than 500 watt, the chamber is carrying sputtering deposition process out and the process has the efficient bombardment on the target and than deposited on the wafer, and no plasma damage issue is concerned. Such that the copper seed layer and barrier layer are getting more conformal on the sidewall of the deep trench, and than the void will not exist in subsequently metal filling process.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross-sectional schematic diagram illustrating dielectric layer applied on damascene structure in accordance with the prior art;

FIG. 2 is a cross-sectional schematic diagram for forming a metal filling in deep trench in accordance with the prior art;

FIG. 3 is a cross-sectional schematic diagram for forming a deep trench with the void in accordance with the prior art;

FIG. 4 is a cross-sectional schematic diagram illustrating dielectric layer applied on damascene structure in accordance with a method disclosed herein;

FIG. 5 is a cross-sectional schematic diagram illustrating a conductive seed layer and a barrier layer formed conformal after treatment by sputtering process in accordance with a method disclosed herein;

FIG. 6 is a cross-sectional schematic diagram illustrating a metal filling a deep trench in accordance with a method disclosed herein; and

FIG. 7 is a cross-sectional schematic diagram illustrating a deep trench structure in accordance with a method disclosed herein.

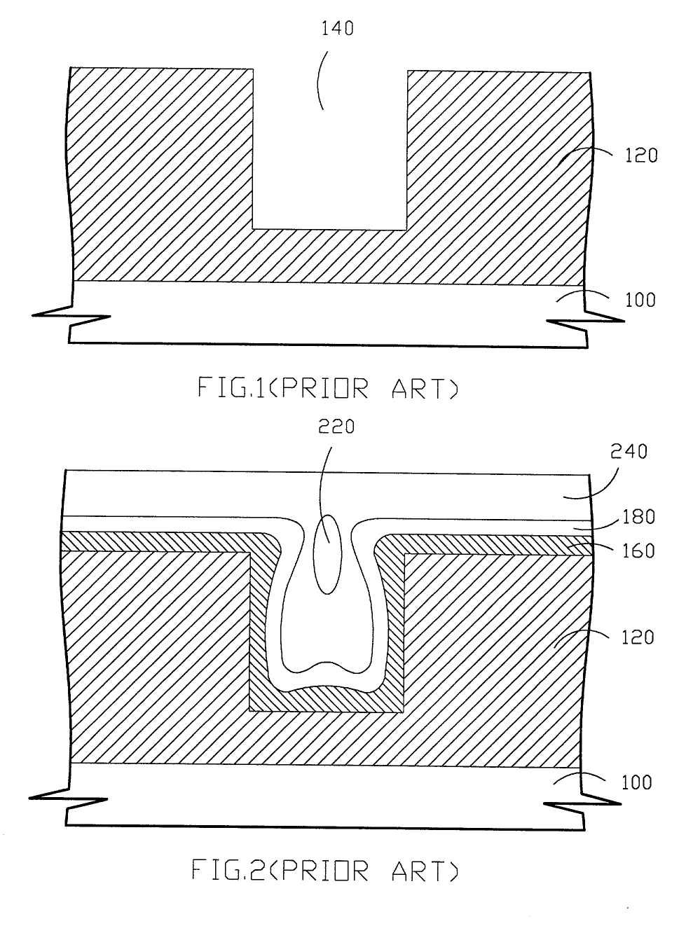

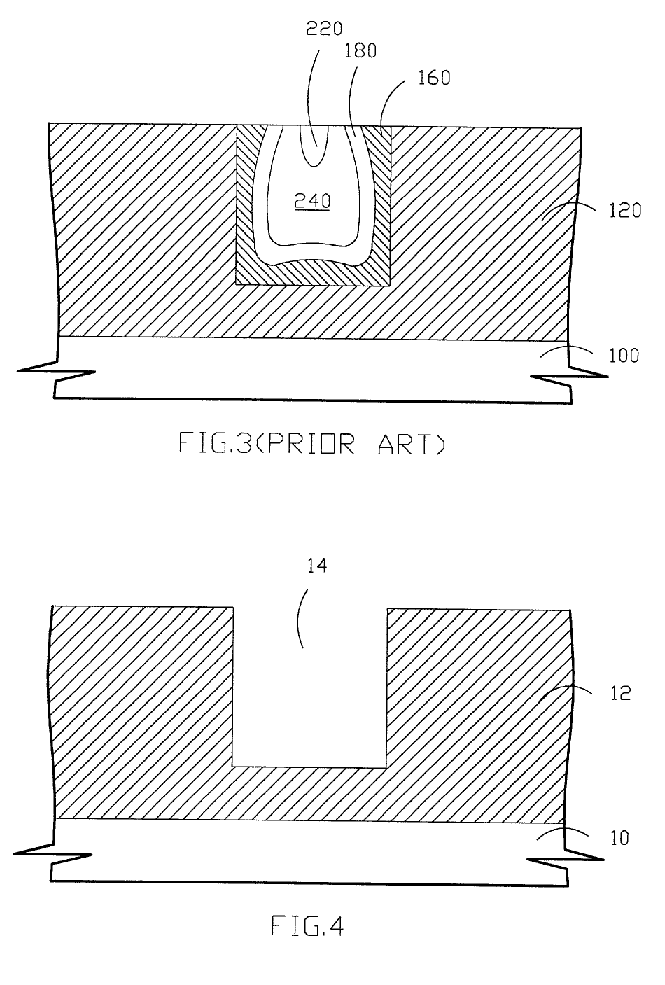

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

In this invention is provided a method to add an extra sputtering etching process after barrier layer/conductive seed layer deposition process to get more conformal barrier layer/conductive seed layer and improve the metal fill capability and metal reliability performance.

Referring to FIG. 4, is illustrating the formation of deep trench 14 on a substrate 10. A dielectric layer 12 is formed on a substrate 10. Then, a photoresist layer is deposited, exposed, and developed on the dielectric layer 12 by the use of know photolithography techniques. Then, an etching process is performed on the dielectric layer 12 to form a deep trench 14, wherein the deep trench 14 within the dielectric layer 12 and above the substrate 10.

Referring to FIG. 5, the wafer is placed in the pre-sputtering chamber. In general, the most common used barrier layer materials include Ti/TiN (titanium/titanium nitride), WN (tungsten nitride), Ta (tantalum) and TaN (tantalum nitride). The reason for having a barrier layer 16 is to increase the adhesive strength of subsequently deposited conductive material as well as to prevent the diffusion of conductive material to the dielectric layer 12. Next, a copper seed layer 18 is deposited on the barrier layer 16 by PVD procedure (Physical vapor deposition).

In general, the pre-sputtering chamber is always used as sputtering etching, and the power is lower than about 200 watt. In this embodiment, when the power of chamber is lower than 200 watt, the process is carrying out sputtering etching, and at this power, the charging issue on the wafer surface can be avoided. However, the barrier layer 16 and copper seed layer 18 is not mature to provide a conformal layer in deep trench 14 and the poor-step coverage is a problem for metal layer filling in the deep trench 14 such that the void is formed in high aspect-ratio trench 14. In order to solve above-mentioned drawback, in this embodiment is to use optimum power in sputtering chamber such that the ion with positive charge is accelerated the speed by potential difference between the plasma and electrode to bombard on the wafer. The metal atom on surface of trench top corner is sputtered by the ion bombarded, if the weight for ion is sufficiently.

For this reason, in order to avoid the step coverage in subsequently metal filling process, the excess copper seed layer 18 is removed by sputter-etching process. When the power is lower than about 200 watt in sputtering chamber, the chamber is carrying a sputter-etching process on the wafer to remove the excess copper seed layer 18 and the copper seed layer 18 and barrier layer 16 are getting more conformal in the deep trench 14, and than the void will not exist in subsequently metal layer filling process. The power is always lower than 200 watt to let efficient bombardment on the wafer, and no plasma damage issue is concerned.

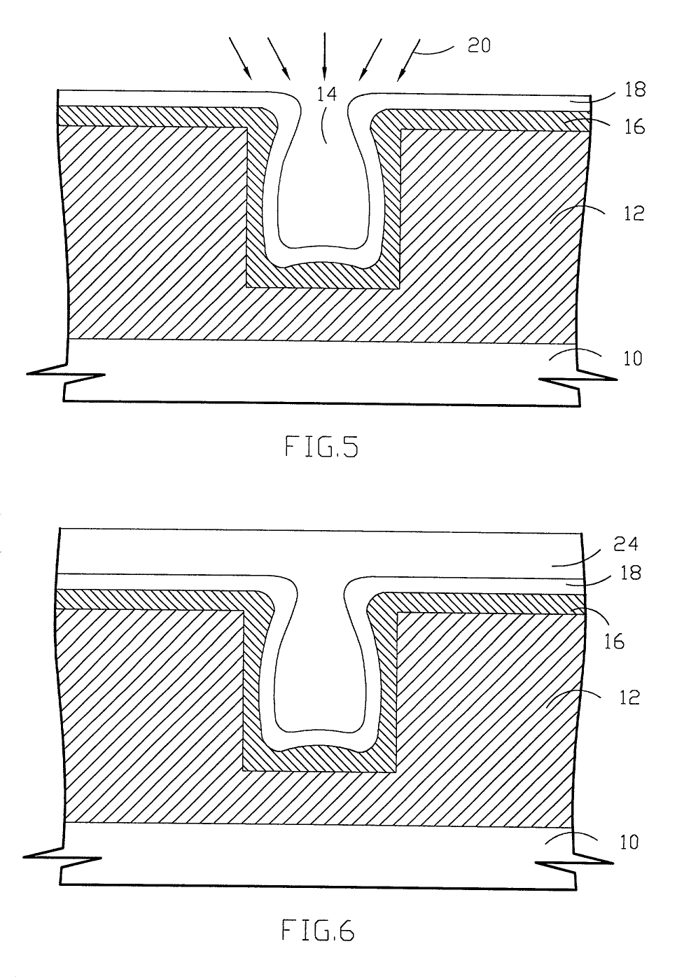

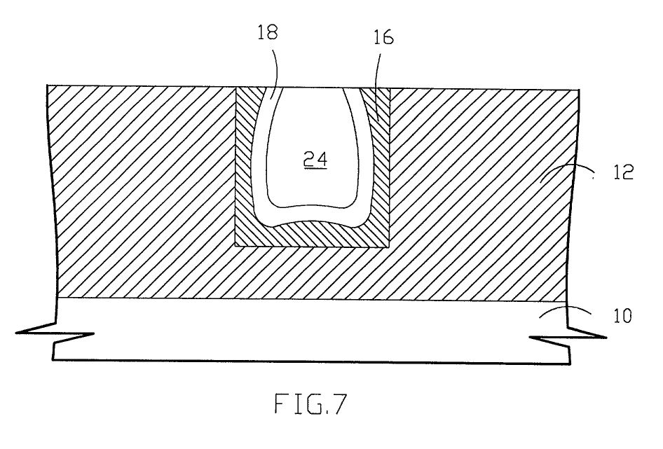

Then, referring to FIG. 6 and FIG. 7, a metal layer 24 is filled in the deep trench 14 by conventional ECD method (electrochemical deposition method). Next, a polishing process such as CMP method (chemical mechanical polishing method) is performed on the metal layer 24 to remove the excess metal layer 24 on the dielectric layer 12. Thereafter, a metal plug is formed in the deep trench 14.

According to above-mentioned description, in order to avoid the void is existed in the deep trench, the wafer is placed in the sputter chamber, and the copper seed layer 18 and barrier layer 16 are formed un-conformal on the sidewall of the deep trench 14, then the copper seed layer 18 and barrier layer 16 are to be conformal by sputtering etching. So, in subsequently metal filling process, the void is not existed in the deep trench and the metal reliability performance is improved.

Although specific embodiments have been illustrated and described, it will be obvious to those skilled in the art that various modifications may be made without departing from what is intended to be limited solely by the appended claims.

What is claimed is:

1. A method for forming a conformal layer in a trench, said method comprising:
providing a substrate having a trench therein;
forming a poor step-coverage layer in said trench; and
etching said poor step-coverage layer to make said conformal layer in said trench.

2. The method according to claim 1, wherein said poor-step coverage layer comprises a barrier layer.

3. The method according to claim 2, further comprising a conductive seed layer on said barrier layer.

4. The method according to claim 3, wherein said etching said poor-step coverage layer comprises a sputter-etching process.

5. The method according to claim 4, wherein the power of said sputter-etching process is lower than about 200 watt.

6. A method for improving the metal filling in deep trench, said method comprises:
providing a substrate having a deep trench therein, and a barrier layer on sidewall of said deep trench, and a conductive seed layer on said barrier layer;
etching said conductive seed layer;
filling a metal layer in said deep trench; and
polishing said metal layer to remove excess said metal layer on said substrate.

7. The method according to claim 6, wherein said depositing said conductive seed layer comprises a physical vapor deposition method.

8. The method according to claim 7, wherein the material of said conductive seed layer comprises copper.

9. The method according to claim 8, wherein said etching said conductive seed layer comprises a sputter-etching process.

10. The method according to claim 9, wherein the power of said sputter-etching process is lower than about 200 watt.

11. The method according to claim 6, wherein the material of said metal layer comprises copper.

12. A method for forming a deep trench, said method comprises:
providing a substrate having a dielectric layer thereon;
forming a photoresist layer on said dielectric layer;
etching said dielectric layer to form a deep trench therein;
depositing a barrier layer on sidewall of said deep trench;
physical vapor depositing a copper seed layer on said barrier layer;
etching said copper seed layer;
depositing a metal layer in said deep trench; and
chemical mechanical polishing said metal layer to remove excess said metal layer on said substrate.

13. The method according to claim 12, wherein said etching said copper seed layer comprises a sputter-etching process.

14. The method according to claim 13, wherein the power of said sputter-etching process is lower than about 200 watt.

15. The method according to claim 12, wherein the material of said metal layer comprises copper.
